(19) United States
(12) Patent Application Publication
(10) Pub. No.: US 2009/0008734 A1
(43) Pub. Date: Jan. 8, 2009

(54) SEMICONDUCTOR LIGHT RECEIVING DEVICE AND PHOTOSEMICONDUCTOR MODULE

(75) Inventor: Hideto FURUYAMA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/164,502

(22) Filed: Jun. 30, 2008

(30) Foreign Application Priority Data
Jun. 29, 2007 (JP) 2007-172533

(51) Int. Cl. H01L 31/00

(52) U.S. Cl. 257/435; 257/E31.001

(57) ABSTRACT

A semiconductor light receiving device includes: a light receiving section made of a semiconductor provided on a substrate; a mask layer provided above the light receiving section and having an opening configured to limit an irradiation area of the light receiving section; and a light scattering section provided in at least part of a light incident path in the opening and including a transparent material and light scattering particles dispersed in the transparent material. Light incident on the light receiving section passes through the light scattering section before being incident on the light receiving section.

### CROSS-REFERENCE TO RELATED APPLICATIONS

This application is based upon and claims the benefit of priority from the prior Japanese Patent Application No. 2007-172533, filed on Jun. 29, 2007; the entire contents of which are incorporated herein by reference.

### BACKGROUND OF THE INVENTION

The performance improvement of electronic devices such as bipolar transistors and field-effect transistors has dramatically increased the operating speed of large-scale integrated circuits (LSI). However, despite high speed operation inside LSI, the interconnection speed at the level of the printed circuit board on which the LSI is mounted is set lower than inside LSI, and the interconnection speed at the level of the rack on which the printed circuit board is installed is set even lower. These are attributed to the increase of transmission loss, noise, and electromagnetic interference associated with the increase of operating frequency, because a longer interconnect requires a lower operating frequency in order to ensure adequate signal quality. Hence, a recent growing trend in electrically interconnected apparatuses is that mounting technology is more dominant in system performance than LSI speed.

In view of the foregoing problem with electrically interconnected apparatuses, some proposals have been made for an optically interconnected apparatus, which includes optical interconnection between LSIs. Optical interconnection has little frequency dependence of loss in the frequency range from DC to 100 GHz or more, and free from electromagnetic interference with the interconnect path and noise due to ground potential difference, allowing interconnection at several 10 Gbps to be easily realized.

Cost-effective optical interconnection requires an optical transmission system that can ensure large mounting margin and operating margin with simple configuration. For example, JP-A 2000-277761(Kokai) (hereinafter referred to as Patent Document 1) and JP-A 2004-241630 (Kokai) (hereinafter referred to as Patent Document 2) disclose conventional techniques for ensuring mounting margin in the optical coupling of a semiconductor light receiving device.

### SUMMARY OF THE INVENTION

According to an aspect of the invention, there is provided semiconductor light receiving device including: a light receiving section made of a semiconductor provided above a substrate; a mask layer provided on the light receiving section and having an opening configured to limit an irradiation area of the light receiving section; and a light scattering section provided in at least part of a light incident path in the opening and including a transparent material and light scattering particles dispersed in the transparent material, light incident on the light receiving section passing through the light scattering section before being incident on the light receiving section.

According to another aspect of the invention, there is provided a semiconductor light receiving device including: a light receiving section made of a semiconductor provided on a substrate; a mask layer provided on the light receiving section and having an opening configured to limit an irradiation area of the light receiving section; and a light scattering section provided on the mask layer configured to cover the opening, including a transparent material and light scattering particles dispersed in the transparent material and allowing at least part of incident light from an upper surface to be incident on the light receiving section.

According to another aspect of the invention, there is provided a photosemiconductor module including: a semiconductor light receiving device; and one of an optical fiber and an optical waveguide with its light emitting end facing the upper surface of the light scattering section, the semiconductor light receiving device including: a light receiving section made of a semiconductor provided above a substrate; a mask layer provided on the light receiving section and having an opening configured to limit an irradiation area of the light receiving section; and a light scattering section provided in at least part of a light incident path in the opening and including a transparent material and light scattering particles dispersed in the transparent material, light incident on the light receiving section passing through the light scattering section before being incident on the light receiving section.

### BRIEF DESCRIPTION OF THE DRAWINGS

FIG. 1 is a perspective view showing the schematic configuration of a semiconductor light receiving device according to a first embodiment;

FIGS. 2A to 2C are cross-sectional views showing the schematic configuration of a semiconductor light receiving device according to a second embodiment;

FIGS. 3A and 3B are cross-sectional views showing the schematic configuration of a semiconductor light receiving device according to a third embodiment;

FIGS. 4A and 4B are a perspective view and a cross-sectional view showing the schematic configuration of a semiconductor light receiving device according to a fourth embodiment;

FIGS. 5A to 5C are a perspective view and cross-sectional views showing the schematic configuration of a semiconductor light receiving device according to a fifth embodiment; and

FIG. 6 is a cross-sectional view showing the schematic configuration of a photosemiconductor module according to a sixth embodiment.

### DETAILED DESCRIPTION OF THE INVENTION

In the conventional technique of Patent Document 1, a resin-molded lens is used as an envelope for a semiconductor light receiving device, which allows light reception at a wide angle. However, in the conventional configuration using a lens as an envelope, it is difficult to independently array optically interconnected light receiving sections at high density. In the conventional technique of Patent Document 2, a small lens is disposed on the light receiving section of a semiconductor light receiving device, which achieves the same effect as Patent Document 1. However, in the conventional configuration with a lens disposed on the light receiving section, in the case where a refractive index matching material for blocking reflected return light is provided at the optical coupling to an optical transmission line (such as an optical fiber), the lens effect is difficult to achieve because of small refractive index difference between the lens and the refractive index matching material.

Thus, unfortunately, conventional optical interconnections have difficulty in high-density parallel connection, and difficulty in addressing reflected return light, which is relevant to using a semiconductor laser as a light source, that is, difficulty in high-speed optical interconnection. Furthermore, in the case where a multi-mode fiber, which facilitates optical coupling on the light emitting device side, is used in the above conventional techniques, the area in which the semiconductor light receiving device can receive all the transmission modes is narrow. Consequently, modal noise is likely to occur, and unfortunately decreases operating margin or mounting margin.

To solve these problems, according to the embodiments of the invention, the light receiving device is provided with a light receiving mask and a light scattering mechanism to reduce variation in the light receiving level and prevent modal noise against optical coupling misalignment.

The embodiments of the invention will now be described with reference to the drawings. While several specific materials are referred to in the description, the embodiments can be similarly practiced using any materials suitable for a semiconductor light receiving device, and the invention is not limited to the following embodiments. Furthermore, the following description will be made by extracting a discrete light receiving device. However, it is understood that the light receiving devices can be integrated into an array device, and any peripheral configuration such as a transimpedance amplifier, not described in the embodiments of the invention, can be optionally added and integrated. Furthermore, the following description focuses on a so-called PIN photodiode serving as a functional structure of the semiconductor light receiving device. However, the description is applicable to various semiconductor light receiving devices such as an MSM (metal-semiconductor-metal) photodiode, photoconductor, and phototransistor.

### FIRST EMBODIMENT

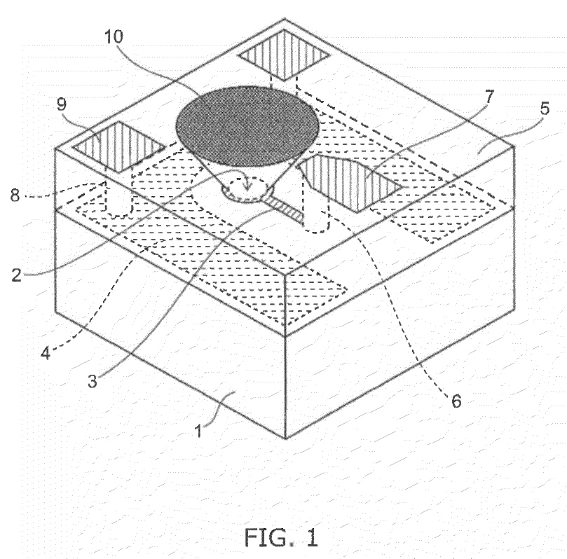

FIG. 1 is a perspective view showing the schematic configuration of a semiconductor light receiving device according to a first embodiment of the invention. In this description, GaInAs/InP-based materials are illustratively used as specific constituent materials. However, as described above, it is also possible to use other materials such as GaAlAs/GaAs-based, SIGe/Si-based, GaN/Si-based, and SiC/Si-based materials. Furthermore, the light receiving section made of the above semiconductor materials can be laminated with a glass substrate or ceramic substrate after the original substrate is removed.

In FIG. 1, the semiconductor light receiving device includes an n-type InP substrate 1, a light receiving section 2, a p-side electrode 3 (such as Au/Pt/Ti and Au/Cr), an n-side electrode 4 (such as AuGe and AuSn), a mask material 5 made of an opaque resin, a p-side through electrode 6 (such as Au), a p-side pad electrode 7 (such as Au/Pt/Ti and Au/Cr), an n-side through electrode 8 (such as Au), an n-side pad electrode 9 (such as Au/Pt/Ti and Au/Cr), and a light scattering resin 10. The mask material 5 can be illustratively made of a polyimide resin, acrylic resin, or epoxy resin mixed with a light absorbing agent (black pigment such as carbon and titanium oxide). The light scattering resin 10 is illustratively made of a polyimide resin, acrylic resin, epoxy resin, or silicone resin mixed with a light scattering agent (fine particles of silica, polystyrene, or titanium oxide) having a particle diameter of several 100 nm (e.g., 200 to 400 nm).

As shown in FIG. 1, the light scattering resin 10 is formed to fill an inverted conical (inverted tapered) opening provided in the mask material 5. Here, the term “inverted conical opening” generically refers to an opening shaped so that a polygonal pyramid or circular cone with its top truncated (frustum of a polygonal pyramid or circular cone) is turned upside down, and an opening having one of these shapes in which the cross section of its slope is other than a straight line (e.g., parabola). In the following description, an opening shaped like an inverted circular cone is taken as an example. In the inverted conical opening, for example, the mask material has a thickness of 70 μm, the slope angle with respect to the substrate surface is 65°, and the opening diameter in the vicinity of the light receiving section 2 is 70 μm (top opening diameter is approximately 135 μm). Here, the light receiving section 2 has a diameter of 80 μm. With this light receiving diameter, an optical signal at 10 Gbps or more can be received by optimizing the impurity concentration and thickness of the light receiving layer.

It is noted that the mask for limiting the irradiation area of the light receiving section may have no contact with the light receiving section. For example, a gap can be provided between the mask and the light receiving section, or a layer of transparent resin or the like can be provided between the mask and the light receiving section.

By this configuration, light incident from above the device is not directly incident on the light receiving section, but subjected to light scattering several times in the light scattering resin 10, where lights with different incident positions and angles are mixed, before reaching the light receiving section 2. At this time, part of the light reaches the mask material 5 from the light scattering resin 10 and is absorbed into the mask material 5. This decreases the amount of input light that reaches the light receiving section as compared with the case without the light scattering resin 10. However, incident lights from various positions and angles are mixed and received, which decreases variation in the light receiving efficiency due to misalignment in the position and angle of the incident light beam. That is, in the semiconductor light receiving device of this embodiment, the light receiving tolerance is increased by optical mixing in the light scattering mechanism at some expense of light receiving efficiency, allowing stable optical coupling (light reception) against optical axis misalignment due to coupling error and temperature variation. Furthermore, in application to reception of light transmitted by a multi-mode optical fiber, lights with various optical transmission modes in the multi-mode optical fiber can be mixed and averagely received. Thus, advantageously, the so-called modal noise can be reduced. Hence, the semiconductor light receiving device of this embodiment can also be stably operated with a multi-mode optical transmission path, allowing the best use of the feature of the multi-mode optical fiber that facilitates simplifying the optical coupling system. Furthermore, it is possible to construct an optical transmission system that is also stable against positional misalignment and temperature variation. That is, optical interconnection with large operating margin and mounting margin can be realized using a simple configuration, facilitating significant cost reduction of optically interconnected apparatuses.

### SECOND EMBODIMENT

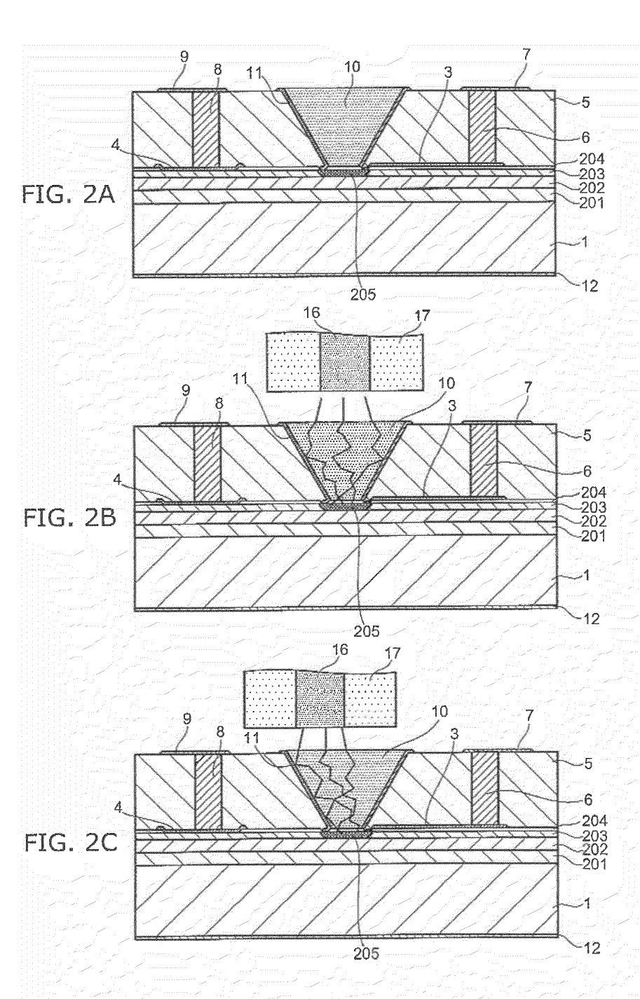

Next, a second embodiment of the invention is described. FIG. 2 is a cross-sectional view of the schematic configuration of the second embodiment of the invention. The description of the elements labeled with the same reference numerals as those in FIG. 1 is omitted. The shape, for example, of the inverted conical opening of the mask material 5 is the same as in the embodiment of FIG. 1. In FIG. 2A, this embodiment includes an n-type InP buffer layer 201, a low-concentration GaInAs light receiving layer 202, an n-type InP window layer 203, a silicon nitride insulating layer 204 (SiNx passivation film), a p-type diffusion layer 205 (e.g., Zn diffusion layer), a light reflecting film 11 (such as Au/Pt/Ti and Au/Cr with the surface made of Au), and a backside electrode 12 (backside n-side electrode, such as AuGe and AuSn). According to this embodiment, the light reflecting film 11 is provided between the light scattering resin 10 and the mask material 5. Scattered light, which is absorbed into the mask material in the embodiment of FIG. 1, is reflected and further scattered to increase light that reaches the light receiving section. FIGS. 2B and 2C illustrate this operation, showing the core 16 and the cladding 17 of an optical fiber, and schematically showing an optical path (ray trajectory) from the optical fiber by a polygonal line. Strictly speaking, the light receiving section 2 in FIG. 1 corresponds to an electric field applied region of the GaInAs light receiving layer 202 underlying the p-type diffusion layer 205. However, in view of the incidence of light through the p-type diffusion layer 205, the p-type diffusion layer 205 and the underlying GaInAs light receiving layer 202 subjected to an electric field are herein collectively referred to as the light receiving section 2.

By this configuration, incident light lying off the light receiving diameter (the diameter of the inverted conical opening in the vicinity of the light receiving section) as shown in FIG. 28 is also introduced into the light receiving section through light scattering and reflection by the light reflecting film 11 at the boundary of the inverted conical opening. For example, in a standard GI (graded index) optical fiber (core diameter 50 μm, NA=0.21), the maximum spread angle of output light is approximately 12°. In the case where this optical fiber applies light to the surface of the semiconductor light receiving device of this embodiment from its vicinity as shown in FIG. 2B, the spread distance at the light receiving surface is approximately 15 μm or more. The maximally spread light outputted from the edge of the optical fiber core is located at approximately 40 μm or more away from the center, and fails to be directly incident on the light receiving section. However, this maximally spread light is returned toward the light receiving section through optical mixing by the light scattering resin 10 and reflection by the light reflecting film 11 at the boundary of the inverted conical opening, and hence can be also incident on the light receiving section. Optical loss is primarily attributed to the backscattered component (scattered toward the light incident direction) of light scattering, which can be adjusted by optimizing the shape of the inverted conical opening on which the light reflecting film 11 is formed and the particle diameter, shape, and content of the light scattering agent added to the light scattering resin 10. Furthermore, also in the case where the optical fiber for light input is located off-axis to some extent as shown in FIG. 2C, the increase of optical coupling loss can be prevented by the focusing effect of the light reflecting film 11 at the boundary of the inverted conical opening. In the case of the standard GI optical fiber described above, the increase of optical loss can be substantially prevented up to an axial misalignment of 20 μm or more.

Thus, in the semiconductor light receiving device of this embodiment, the optical line for inputting light has a large allowance for positional misalignment. Furthermore, in contrast to the continuous dependence of optical loss on the off-axis distance as in the lens coupling (e.g., Patent Document 1), this embodiment provides a region with little optical coupling loss up to a certain off-axis distance. Hence, in the case of using a multi-mode optical fiber for optical transmission as described above, modal noise, which tends to interfere with multi-mode optical transmission, presents no problem up to a certain off-axis distance. Furthermore, this embodiment allows certain axial misalignment due to temperature variation and assembly error as in the embodiment of FIG. 1.

In the case of lens coupling, for example, there is a region with a relatively small optical loss. However, the optical loss in this case directly corresponds to optical mode loss, which leads up to the so-called modal noise. Hence, lens coupling has the potential problem of modal noise also in the case where the amount of optical loss is negligible. In contrast, this embodiment solves this problem, and further has the advantage of being able to ensure allowance for the axial misalignment of optical lines. That is, this embodiment provides mounting margin for the axial misalignment of optical lines as well as operating margin for modal noise. Hence the optical line can be adequately coupled to the semiconductor light receiving device using a simple configuration such as the so-called butt-joint coupling configuration as shown in FIG. 2B.

In FIGS. 1 and 2, the gap between the optical fiber and the light scattering resin 10 is left intact in use. However, in the case of using a semiconductor laser on the light transmitting side to construct a butt-joint coupling similar to the light receiving side of this embodiment, residual reflection (several %) at the end of the optical fiber or other optical line is optically fed back to the semiconductor laser on the light transmitting side, causing the semiconductor laser to produce the so-called optical feedback noise. To prevent this phenomenon, the gap between the optical line and the light scattering resin can be filled with a refractive index matching resin having a refractive index close to the equivalent refractive index of the optical line. Also in this case, the effect of this embodiment described above is similarly achieved, and more advantageously, the optical distance is reduced by a factor of the refractive index of the filling resin, thereby increasing the allowance for axial misalignment described above. Incidentally, in the case of the semiconductor light receiving device with a small lens formed on the light receiving section as disclosed in Patent Document 2, filling with a refractive index matching material as described above extremely decreases the refractive index difference between the lens and the surroundings. Thus, the lens effect is substantially impaired, and the device loses its function. In contrast, the semiconductor light receiving device of this embodiment retains its function irrespective of whether the surrounding medium is air or resin.

Also in this embodiment, the resin layer 5 (mask material) is preferably made of an opaque resin. That is, some gap (a portion with no light reflecting film) is needed between the light reflecting film 11 and the insulating layer 204 in FIG. 2 to prevent the increase of electrical parasitic capacitance due to the reflecting film 11. Light leaking from this gap is a kind of stray light. Irradiation of a region away from the p-type diffusion region 205 with this stray light produces a diffusion current in the region, which is not subjected to the electric field induced by reverse-biased pn junction. This diffusion current is a light receiving current having a considerably slower response than the drift current in the electric field applied portion. To prevent the diffusion current due to this leakage light or light not incident on the overlying inverted conical opening, the resin layer 5 is preferably made of an opaque resin. As another possible structure, a light blocking layer can be provided between the insulating layer 204 and the resin layer 5, which can be transparent. For example, a light blocking resin containing carbon black can be interposed between the insulating layer 204 and the resin layer 5.

### THIRD EMBODIMENT

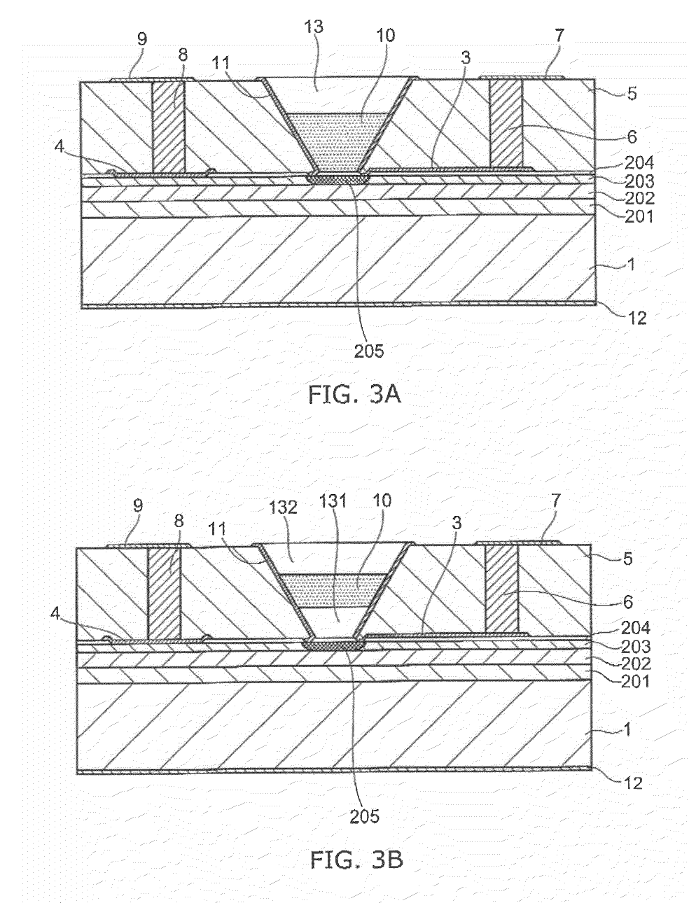

FIG. 3 shows a cross-sectional configuration of a third embodiment of the invention, where the description of elements in common with the first and second embodiment is omitted. In FIG. 3A, this embodiment includes a transparent resin 13. In this embodiment, incident light is focused to some extent by the focusing effect of the inverted conical opening (tapered opening), that is, the upper tapered portion of the light reflecting film 11, before being incident on the light scattering resin 10. This decreases the scattering distance in the light scattering resin 10, thereby reducing optical loss due to backscattering. The thickness of the transparent resin 13 is illustratively 30 μm (the thickness of the light scattering resin 10 is 40 μm).

The transparent resin 13, which is provided with the focusing effect based on a tapered reflecting configuration, is preferably a resin like the above refractive index matching resin adapted to the optical fiber. To form the transparent resin 13, the portion thereof can be formed as a gap and filled with a transparent resin (refractive index matching resin) at the time of coupling to the optical fiber. However, preferably, the tapered opening is filled beforehand in the step of manufacturing a semiconductor light receiving device. Thus, when an optical fiber or other optical line is placed closed thereto and the surrounding space is filled, air bubbles can be prevented from remaining in the tapered opening.

As described above, a light collector and a light mixer are realized by filling the tapered opening with a transparent resin and a light scattering resin, respectively. Furthermore, as shown in FIG. 3B, focusing and scattering of light can be combined in multiple stages. In FIG. 3B, reference numerals 131, 132 denote a transparent resin. The portions 131, 132 constitute a tapered light collector. This configuration decreases the light scattering distance, allowing reduction of optical loss due to backscattering, but may be inadequate as a light mixer. In that case, the addition ratio of the light scattering agent in the light scattering resin 10 can be adjusted for optimization. Such configuration and optimization can be determined by taking the desired optical coupling efficiency and tolerance range into consideration.

### FOURTH EMBODIMENT

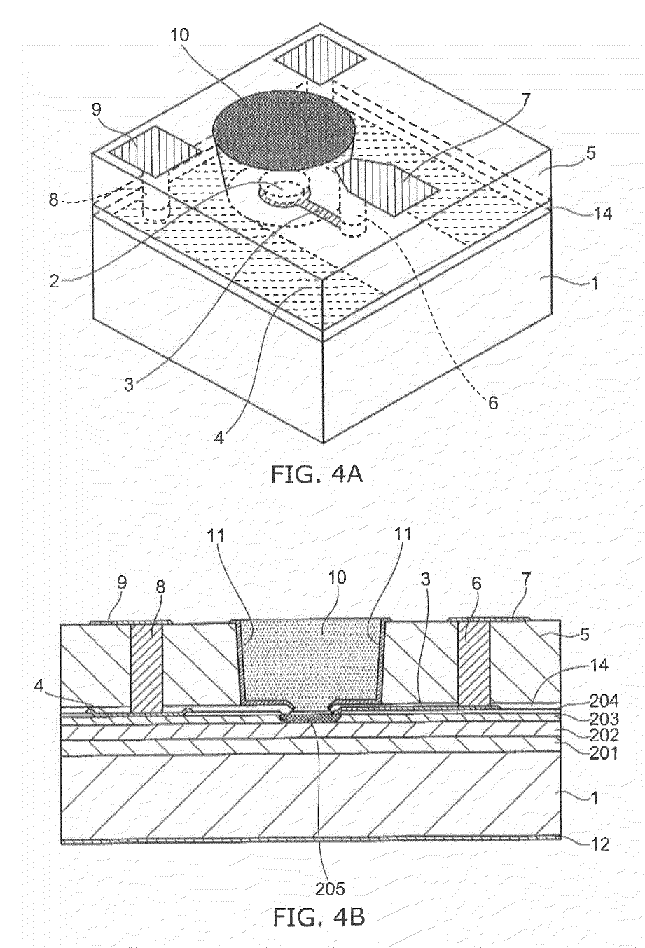

FIG. 4A is a perspective view showing the configuration of a fourth embodiment of the invention, and FIG. 4B is a cross-sectional view thereof. The description of the same elements as those in the previous embodiments is omitted. In the previous embodiments, the light scattering resin 10 has an inverted taper shape. However, if it can be irradiated with a sufficient amount of light, an inner wall of a nearly vertical cross section can be used to achieve only the optical mixing effect. In this case, the mask material 5 does not need to be processed into a tapered shape, but can be processed by simple photolithography using a photosensitive resin, which facilitates manufacturing.

In FIGS. 4A and 4B, this embodiment includes a stopper layer 14 for facilitating processing, which is illustratively made of polyimide having a thickness of 2 μm and provided with an opening at the light receiving section. A mask material 5 made of an opaque resin is formed thereon with a thickness of e.g. 20 μm, which is subjected to simple digging processing to form a hollow exposing the stopper layer 14 and the light receiving section as shown. Subsequently, the inner surface of the hollow outside the light receiving section is covered with a light reflecting film 11, and the hollow can be filled with a light scattering resin 10 as shown. In this case, if the light reflecting film 11 is made of metal, the stopper layer 14 can serve as a spacer to reduce the increase of parasitic capacitance with the electrode 3.

If the stopper layer 14 is made of an opaque resin (e.g., a polyimide resin, acrylic resin, or epoxy resin mixed with a light absorbing agent (black pigment such as carbon and titanium oxide), the portion 5 does not need to be made of an opaque resin. In this case, the portion 14 serves as a mask material, the portion 5 can be illustratively made of photosensitive polyimide, and the above digging processing can be performed by photolithography using pattern exposure and development.

### FIFTH EMBODIMENT

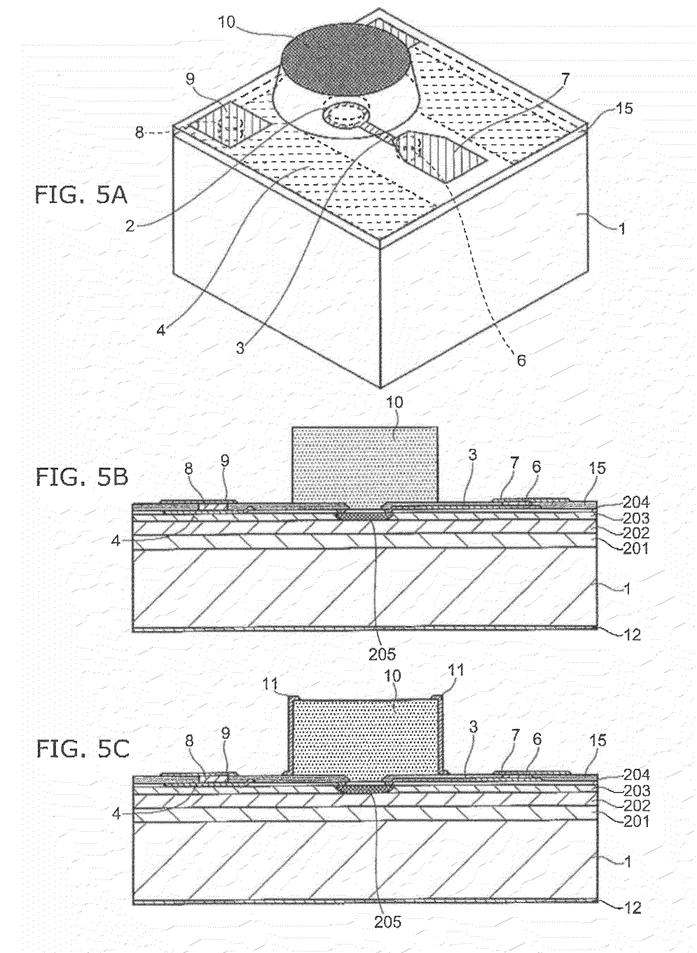

FIG. 5A is a perspective view showing the configuration of a fifth embodiment of the invention, and FIG. 5B is a cross-sectional view thereof. The description of the same elements as those in the previous embodiments is omitted. In the embodiment of FIG. 4, the light scattering resin 10 is formed in an embedded manner. In contrast, as shown in FIGS. 5A and 5B, the portion surrounding the light scattering resin 10 can be removed.

In this case, the portion 15 can be made of an opaque film to serve as a mask material. The opaque film 15 is illustratively made of a polyimide resin mixed with a light absorbing agent (black pigment such as carbon and titanium oxide) and having a thickness of 2 μm. Then, the electrodes 7, 9 are processed, a light scattering resin 10 is provided on the entire surface, and the surrounding portion is selectively removed as shown. Alternatively, the light scattering resin 10 can be formed by selective coating using a dispenser or screen printing. The light scattering resin 10 may have a substantially vertical side wall. The thickness of the light scattering section 10 may be larger than the thickness of the opaque film 15.

In the case where the surrounding space is filled with a refractive index matching material for coupling to an optical fiber as described above, scattering light is diffused into the surroundings of the light scattering resin 10. Hence, as shown in FIG. 5C, a light reflecting film 11 can be added. In this case, the opening of the light incident portion can be made smaller than the size of the light scattering resin 10 to reflect backscattered light again downward. This facilitates reducing optical loss.

### SIXTH EMBODIMENT

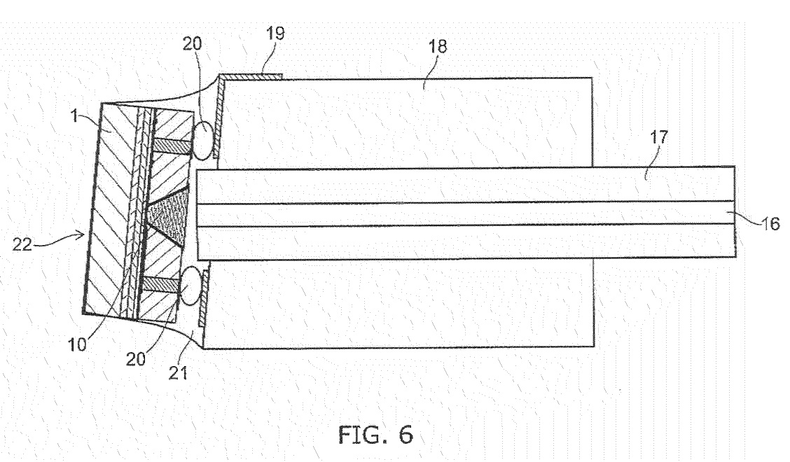

FIG. 6 is a schematic cross-sectional view of a photosemiconductor module according to a sixth embodiment of the invention. The semiconductor light receiving device 22 shown in FIG. 2, for example, is flip-chip mounted on an optoelectric ferrule 18 provided with a three-dimensional plated wire 19 using Au stud bumps 20. The optical device mounting surface of the optoelectric ferrule 18 can be sloped with respect to the vertical surface as shown so that residual reflected light from the surface of the light scattering resin 10 is prevented from being optically coupled to the optical fiber core 16. The slope angle of the optoelectric ferrule 18 is illustratively 8 degrees. Furthermore, filling with a transparent resin 21 is preferable to reduce reflected light itself at the end facet of the optical fiber and the surface of the light scattering resin 10. The transparent resin 21 also serves as an underfill for the semiconductor light receiving device 22. The transparent resin 21 can be illustratively made of an epoxy resin, silicone resin, and acrylic resin. The transparent resin 21 is preferably made of a refractive index matching resin having a refractive index nearly equal to that of the optical fiber to reduce return light to the optical fiber. Thus, also in the case of using a semiconductor laser on the light transmitting side, occurrence of optical feedback noise can be prevented.

In this embodiment, optical axis variation due to temperature variation is absorbed by the effect of expanding the light receiving tolerance as described above so that stable optical coupling can be maintained. Furthermore, also in the case of using a semiconductor laser as a light source for high-speed optical transmission, occurrence of modal noise can be prevented. Thus, a photosemiconductor module with high reliability in optical transmission can be realized at low manufacturing cost.

### Variations

The invention is not limited to the above embodiments. The examples in the above embodiments of the invention are presented only for illustrative purposes to describe the configuration. For example, the elements such as the light receiving layer, mask layer, light scattering section, opening, light reflecting film, and the material of the optical fiber can be replaced by other means (configuration, material, dimension, shape, and placement) within the spirit of the invention. Furthermore, the above embodiments can be suitably practiced in combination. That is, the invention can be practiced in various modifications without departing from the spirit of the invention.

The above embodiments and the variations thereof can provide a semiconductor light receiving device and a photosemiconductor module which facilitates constructing parallel optical interconnection with high density and also facilitates addressing reflected return light in the case of using a semiconductor laser as a light source. Furthermore, also in the case of using a multi-mode fiber, which is easy to be optically coupled to a light emitting device, the area in which all the transmission modes can be received is large, consequently preventing occurrence of modal noise. Hence, a semiconductor light receiving device and a photosemiconductor module with large operating margin and mounting margin can be realized. Thus, the present invention can significantly facilitate practical application and cost reduction of optical interconnection apparatuses, contributing greatly to the sophistication of information and communication equipment.

1. A semiconductor light receiving device comprising:
a light receiving section made of a semiconductor provided on a substrate;
a mask layer provided above the light receiving section and having an opening configured to limit an irradiation area of the light receiving section; and
a light scattering section provided in at least part of a light incident path in the opening and including a transparent material and light scattering particles dispersed in the transparent material,
light incident on the light receiving section passing through the light scattering section before being incident on the light receiving section.

2. The semiconductor light receiving device according to claim 1, wherein the opening expands upward.

3. The semiconductor light receiving device according to claim 1, wherein an inner wall of the opening is covered by a light reflecting film.

4. The semiconductor light receiving device according to claim 2, wherein the light scattering section partly occupy the opening at a nearer part of the opening.

5. The semiconductor light receiving device according to claim 1, wherein the light scattering section partly occupy the opening at middle part of the opening.

6. The semiconductor light receiving device according to claim 5, wherein transparent material is provided on both sides of the light scattering section in the opening.

7. The semiconductor light receiving device according to claim 1, wherein the light scattering section has a sidewall covered with a light reflecting film.

8. The semiconductor light receiving device according to claim 1, wherein the opening expands upwards the opening has a surface covered with a light reflecting film, and at least part of the light scattering section is formed inside the upward expanding region of the opening.

9. The semiconductor light receiving device according to claim 1, wherein an inner wall of the opening is substantially vertical.

10. The semiconductor light receiving device according to claim 8, wherein the opening includes a focusing section made of a transparent resin and the light scattering section combined in multiple stages.

11. The semiconductor light receiving device according to claim 1, further comprising a stopper layer made of opaque material and having an opening configured to limit an irradiation area of the light receiving section between the light receiving section and the mask layer,
the opening in the mask layer being larger than the opening in the stopper layer.

12. The semiconductor light receiving device according to claim 11, wherein the inner wall of the opening in the mask layer is covered with a light reflecting film.

13. The semiconductor light receiving device according to claim 12, wherein the surface of the stopper layer exposed to bottom of the opening in the mask layer is covered with the light reflecting film.

14. A semiconductor light receiving device comprising:
a light receiving section made of a semiconductor provided on a substrate;
a mask layer provided above the light receiving section and having an opening configured to limit an irradiation area of the light receiving section; and
a light scattering section provided on the mask layer configured to cover the opening, including a transparent material and light scattering particles dispersed in the transparent material and allowing at least part of incident light from an upper surface to be incident on the light receiving section.

15. The semiconductor light receiving device according to claim 14, wherein the light scattering section has a substantially vertical side wall.

16. The semiconductor light receiving device according to claim 14, wherein the light scattering section has a sidewall covered with a light reflecting film.

17. The semiconductor light receiving device according to claim 14, wherein a thickness of the light scattering section is larger than a thickness of the mask layer.

18. A photosemiconductor module comprising:
a semiconductor light receiving device; and
one of an optical fiber and an optical waveguide with its light emitting end facing the upper surface of the light scattering section,
the semiconductor light receiving device including:
a light receiving section made of a semiconductor provided on a substrate;
a mask layer provided above the light receiving section and having an opening configured to limit an irradiation area of the light receiving section; and
a light scattering section provided in at least part of a light incident path in the opening and including a transparent material and light scattering particles dispersed in the transparent material,
light incident on the light receiving section passing through the light scattering section before being incident on the light receiving section.

19. The photosemiconductor module according to claim 18, wherein the optical fiber is a multi-mode fiber.

20. The photosemiconductor module according to claim 18, further comprising: a transparent resin filling a gap between the light incident surface of the light scattering section and the light emitting end of the optical fiber or the optical waveguide.
